(19) United States
(12) Patent Application Publication
(10) Pub. No.: US 2024/0234243 A1
(43) Pub. Date: Jul. 11, 2024

(54) ELECTRONIC ASSEMBLIES WITH THERMAL INTERFACE STRUCTURE

(71) Applicant: Tesla, Inc., Austin, TX (US)

(72) Inventors: Aydin Nabovati, Toronto (CA); Mengzhi Pang, Cupertino, CA (US); Mohamed Nasr, Sunnyvale, CA (US)

(21) Appl. No.: 18/560,325

(22) PCT Filed: May 16, 2022
(86) PCT No.: PCT/US2022/029463

§ 371 Date: Nov. 10, 2023

Related U.S. Application Data
(60) Provisional application No. 63/190,122, filed on May 18, 2021.

(51) Int. Cl. H01L 23/373; H01L 21/48; H01L 23/00

(52) U.S. Cl. CPC H01L 23/3735; H01L 21/4882; H01L 23/3736; H01L 23/3737; H01L 24/29; H01L 24/32; H01L 24/83; H01L 2224/29193; H01L 2224/32245; H01L 2224/83091; H01L 2924/1427; H01L 2924/3512

(57) ABSTRACT

Electronic assemblies such as system on a wafer assemblies are disclosed. The assembly can include an electronic component that has a first side, a heat removing structure that is coupled to the first side of the electronic component, and a thermal interface structure that includes a thermal interface layer and an adhesion layer. The electronic component can be a system on a wafer (SoW). The thermal interface layer is positioned between the first side of the electronic component and the heat dissipation structure. The adhesion layer is positioned between the heat removing structure and the thermal interface layer. With the thermal interface structure, the electronic component and the heat removing structure can be attached together with relatively lower pressure.

### CROSS-REFERENCE TO RELATED APPLICATION

This application claims the benefit of U.S. Provisional Patent Application No. 63/190,122, titled “SYSTEM ON A WAFER ASSEMBLIES WITH THERMAL INTERFACE STRUCTURE,” filed May 18, 2021, the disclosure of which is incorporated herein by reference in its entirety and for all purposes.

### TECHNICAL FIELD

The present disclosure relates generally to electronic assemblies, such as system on a wafer assemblies, and more specifically to such assemblies with a thermal interface structure.

### BACKGROUND

A system on a wafer assembly includes a system on a wafer (SoW) that includes an array of integrated device dies. The SoW generates heat during operation. A heat removing structure (e.g., cooling solution) is attached to the SoW to remove heat generated by the SoW. When the SoW and the heat removing structure are bonded together, a compliant highly conductive layer is placed between the SoW and the heat removing structure to facilitate the heat transfer from the SoW to the heat removing structure. Such a layer is commonly referred to as thermal interface material (TIM), which will help create a thermal bridge between the two aforementioned components. Most of the TIMs require a significant pressure on them to yield a desirable thermal performance. Such a pressure can damage the SoW and/or components thereof or adversely impact their long term reliability.

### SUMMARY OF CERTAIN INVENTIVE ASPECTS

In one aspect, an electronic assembly is disclosed. The electronic assembly includes an electronic component that has a first side, a heat removing structure that is coupled to the first side of the electronic component, and a thermal interface structure that includes a thermal interface layer and an adhesion layer. The thermal interface layer is positioned between the first side of the electronic component and the heat removing structure. The adhesion layer is positioned between the heat removing structure and the thermal interface layer.

In one embodiment, the electronic component is a system on a wafer (SoW).

In one embodiment, the thermal interface layer includes a vertically aligned graphite layer that is aligned generally perpendicular to the first side of the electronic component.

In one embodiment, the thermal interface layer includes a carbon nanotube layer.

In one embodiment, a thickness of the thermal interface layer is greater than a thickness of the adhesion layer.

In one embodiment, the adhesion layer includes a horizontally aligned graphite layer that is aligned generally parallel to the first side of the electronic component.

In one embodiment, the thermal interface layer includes a vertically aligned graphite layer that is aligned generally perpendicular to the first side of the electronic component. The adhesion layer can include a horizontally aligned graphite layer that is aligned generally parallel to the first side of the electronic component.

In one embodiment, the adhesion layer includes a metal adhesion layer. The metal adhesion layer can include gold or indium.

In one embodiment, the adhesion layer includes a thermal grease layer. The heat removing structure can include a groove. At least a portion of the thermal grease layer can be disposed in the groove.

In one embodiment, the heat removing structure includes a metal plate.

In one embodiment, the assembly further includes a second adhesion layer between the electronic component and the thermal interface layer. The adhesion layer and the second adhesion layer can include a same material.

In one embodiment, the assembly further includes a control board that is coupled to a second side of the electronic component opposite the first side. The assembly can further include a second heat removing structure between the second side of the electronic component and the control board.

In one aspect, a method of manufacturing an electronic assembly is disclosed. The method includes providing (a) a thermal interface layer between a first side of an electronic component and a heat removing structure and (b) an adhesion layer between the thermal interface layer and the heat removing structure. The method includes applying pressure to bond the electronic component and the heat removing structure by way of the thermal interface layer.

In one embodiment, the electronic assembly is a system on a wafer assembly and the electronic component is a system on a wafer (SoW).

In one embodiment, the thermal interface layer includes a vertically aligned graphite layer that is aligned generally perpendicular to a first side of the electronic component.

In one embodiment, the thermal interface layer includes a carbon nanotube layer.

In one embodiment, a thickness of the thermal interface layer is greater than a thickness of the adhesion layer.

In one embodiment, the adhesion layer includes a horizontally aligned graphite layer that is aligned generally parallel with a first side of the electronic component.

In one embodiment, the adhesion layer includes a metal adhesion layer. The metal adhesion layer includes at least one of gold or indium.

In one embodiment, the adhesion layer includes a thermal grease layer. The heat removing structure can include a groove. At least a portion of the thermal grease layer can be disposed in the groove.

In one embodiment, the method further includes a second adhesion layer between the electronic component and the thermal interface layer. The adhesion layer and the second adhesion layer can include a same material.

In one embodiment, the method further includes providing a control board to a second side of the electronic component opposite the first side. The method can further include providing a second heat removing structure between the second side of the electronic component and the control board.

In one aspect, a wafer assembly is disclosed. The wafer assembly includes a wafer that has a first side, a heat removing structure that is coupled to the wafer, a thermal interface structure that is disposed between and bonding the first side of the wafer and the heat removing structure, and a groove between the wafer and the heat removing structure. The thermal interface structure includes a thermal interface material. At least a portion of the thermal interface material is disposed in the groove.

In one embodiment, the groove is in a surface of the wafer.

In one embodiment, the groove is in a surface of the heat removing structure.

In one embodiment, the thermal interface material includes thermal grease.

In one embodiment, the thermal interface structure includes a thermal interface layer that includes a vertically aligned graphite layer that is aligned generally perpendicular to the first side of the wafer.

In one embodiment, the thermal interface structure includes a thermal interface layer that includes a carbon nanotube layer.

In one embodiment, the assembly further includes a control board that is coupled to a second side of the wafer opposite the first side. The assembly can further include a second heat removing structure between the second side of the wafer and the control board.

### BRIEF DESCRIPTION OF THE DRAWINGS

Specific implementations will now be described with reference to the following drawings, which are provided by way of example, and not limitation.

FIG. 1 shows a schematic cross sectional side view of a system on a wafer (SoW) assembly.

FIG. 2 is a schematic cross sectional side view of a system on a wafer assembly according to an embodiment.

FIG. 3A is a schematic cross sectional side view of a system on a wafer assembly according to another embodiment.

FIG. 3B is a schematic cross sectional side view of a system on a wafer assembly according to another embodiment.

FIG. 3C is a schematic cross sectional side view of a system on a wafer assembly according to another embodiment.

FIG. 4A is a schematic cross sectional side view of a thermal interface structure according to another embodiment.

FIG. 4B is a schematic cross sectional side view of a thermal interface structure according to another embodiment.

FIG. 4C is a schematic cross sectional side view of a thermal interface structure according to another embodiment.

FIG. 5A illustrates a step in a process of manufacturing the assembly of FIG. 3B according to an embodiment.

FIG. 5B illustrates another step in a process of manufacturing the assembly of FIG. 3B according to an embodiment.

FIG. 5C illustrates another step in a process of manufacturing the assembly of FIG. 3B according to an embodiment.

FIG. 6 is a flow chart of a process of manufacturing a system on a wafer assembly according to an embodiment.

FIG. 7A is a schematic cross sectional side view of a system on a wafer assembly according to another embodiment.

FIG. 7B is a schematic cross sectional side view of a system on a wafer assembly according to another embodiment.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

System on a wafer assemblies can include a system on a wafer (SoW) and a heat removing structure that is coupled to the SoW. Bonding surfaces of the SoW and/or the heat removing structure can be rough such that when the surfaces are brought into contact, gaps or voids are formed between the bonding surfaces. A thermal interface material can be provided between the bonding surfaces of the SoW and the heat dissipation structure. The thermal interface material can mitigate and/or prevent formation of the gaps between the bonding surfaces. The thermal interface material can provide better thermal conductivity for heat transfer than air.

However, with certain thermal interface materials, bonding the SoW and the heat removing structure together can involve a relatively high pressure. For example, at least 40 pounds per square inch (psi) is applied to activate certain thermal interface materials for bonding. This can involve about 3000 psi of total force on the SoW. Due to non-uniform SoW stack up tolerance, such force can be a significant concern. The relatively high pressure for bonding can result in wafer cracking and/or other damage to the SoW or other system components in certain instances. The relatively high pressure for bonding can reduce reliability of SoWs and/or related electronics of the SoW assemblies. Further, using a low pressure bonding thermal interface material, such as a liquid form material, as the thermal interface material can have some challenges. For example, the liquid form material may dry out over time and creates voids between the SoW and the heat removing structure.

Various embodiments disclosed herein relate to SoW assemblies with a thermal interface structure that includes an adhesion layer that can achieve low pressure bonding of the SoW and a thermal interface layer with a relatively high thermal conductivity for heat transport, transfer, removal, or dissipation. Such SoW assemblies can achieve good thermal performance without drawbacks associated with high pressure bonding during manufacturing. Various embodiments disclosed herein relate to structures (e.g., a reservoir or a grove) formed with the SoW and/or the heat removing structure for a SoW assembly suited for a low pressure bonding thermal interface material, such as a thermal grease.

Various embodiments disclosed herein may be described in connection with a SoW assembly that includes a SoW. However, any suitable the principles and advantages disclosed herein can be implemented with any suitable electronic assembly that includes an electronic component.

FIG. 1 shows a schematic cross sectional side view of a system on a wafer (SoW) assembly 10. The SoW assembly is an example of an electronic assembly. As illustrated in FIG. 1, the SoW assembly 10 includes a heat removing structure 26 (e.g., a heat dissipation structure), an electronic component (e.g., a SoW 24), voltage regulating modules (VRMs) 16, a cooling system 32, a thermal interface material (TIM) structure 21 that includes a TIM, and a TIM structure 23 that includes a TIM. The TIM structures 21 and/or 23 can comprise any suitable thermal interface structure disclosed herein. In some applications, certain advantages of a thermal interface structure disclosed herein can be pronounced when the thermal interface structure is used as the TIM structure 23. VRMs 16 are examples of electronic modules or electronic components that can be positioned over a wafer with TIM disposed therebetween. Features of this disclosure can be implemented in a system that includes the SoW assembly 10 and/or any other suitable processing system. The SoW assembly 10 can have a high compute density and can dissipate heat generated by the SoW assembly 10.

The stack of components in the SoW assembly 10 is an example of an assembly that can be included in a processing system. Various principles and advantages disclosed herein can be implemented in any other suitable assemblies or systems with TIMs between components.

The SoW 24 and the heat removing structure 26 are coupled together. A TIM structure 23 can be provided between the heat removing structure 26 and the SoW 24. The heat removing structure 26 can dissipate heat from the SoW 24. The heat removing structure 26 can comprise metals, such as copper and/or aluminum. The heat removing structure 26 can alternatively or additionally include any other suitable material with desirable heat dissipation properties. A thermal interface material that is included between the heat removing structure 26 and the SoW 14 can reduce and/or minimize heat transfer resistance between the heat removing structure 26 and the SoW 14.

The SoW 24 and the heat removing structure 26 are coupled together. A TIM structure 23 can be provided between the heat removing structure 26 and the SoW 24. The heat removing structure 26 can dissipate heat from the SoW 24. The heat removing structure 26 can include metal, such as copper and/or aluminum.

The SoW 24 can include an array of integrated circuit (IC) dies. The IC dies can be embedded in a molding material. The SoW 24 can have a high compute density. The array of IC dies can include any suitable number of IC dies. The SoW 24 can be an Integrated Fan-Out (InFO) wafer, for example. InFO wafers can include a plurality of routing layers over an array of IC dies. The routing layers of the InFO wafer can provide signal connectivity between the ICs dies and/or to external components. The SoW 24 can have a relatively large diameter.

The VRMs 16 can be positioned such that each VRM is stacked with an IC die of the SoW 24. In the SoW assembly 10, there is high density packing of the VRMs 16. Accordingly, the VRMs 16 can consume significant power. The VRMs 16 are configured to receive a direct current (DC) supply voltage and supply a lower output voltage to a corresponding IC die of the SoW 24. The SoW assembly 10 includes the TIM structure 21 between the cooling system 32 and the VRMs 16. The TIM structure 21 can improve thermal conductivity between the cooling system 32 and the VRMs 16. The TIM structure 21 can provide adhesion between the cooling system 32 and the VRMs 16. The TIM structure 21 can be provided with the cooling system 32.

The cooling system 32 can comprise any suitable cooling structure. The cooling system 32 can provide active cooling for the VRMs 16. Active cooling can involve coolant, such as liquid coolant, flowing through the cooling system 32.

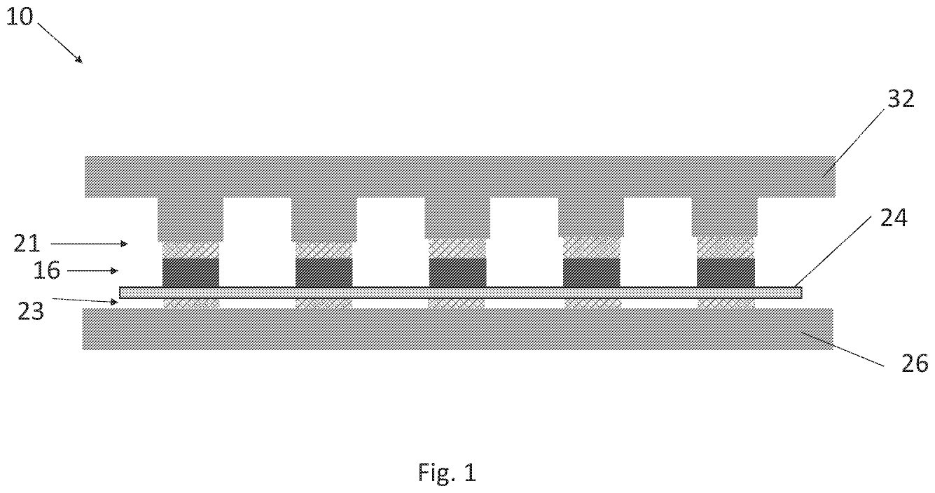

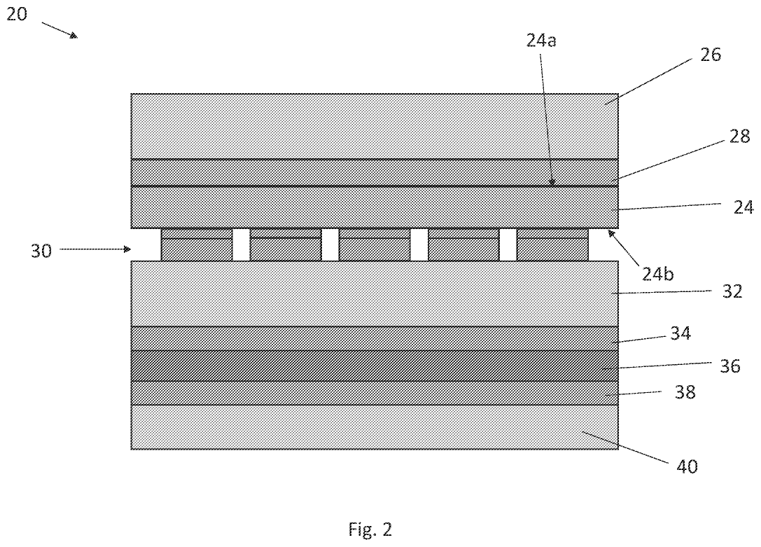

FIG. 2 is a schematic cross sectional side view of a SoW assembly 20 according to an embodiment. The assembly 20 can include a SoW 24 having a first side 24a and a second side 24b opposite the first side 24a, and a heat removing structure 26. The assembly 20 can also include a thermal interface structure 28 that is positioned between the first side 24a of the SoW 24 and the heat removing structure 26. The assembly 20 can also include gap pads 30, a first cooling structure (the cooling system 32), a first intervening layer 34, a control board 36, a second intervening layer 38, and a second cooling structure 40, on the second side 24b of the SoW 24. In some embodiments, the SoW 24 can electrically connect to the control board 36.

The first side 24a of the SoW 24 and/or a surface of the heat removing structure 26 that is coupled to the SoW 24 can have certain surface profile or microscopic roughness. When such surfaces are in contact, a void or gap (e.g., an air gap) may be formed between the two surfaces. The void or gap may reduce and/or interrupt heat transfer between the SoW 24 and the heat removing structure 26. A thermal interface structure 28 between the SoW 24 and the heat removing structure 26 can conform to the surfaces of the first side of the SoW 24 and the heat removing structure 26 to mitigate and/or prevent the formation of the void or gap. Therefore, the heat generated by the SoW 24 can be transferred to the heat removing structure 26 more efficiently with the thermal interface structure 28 than without the thermal interface structure 28. The thermal interface structure 28 can comprise any suitable structure or material. The thermal interface structure 28 can comprise a multi-layer structure as described herein.

In order for the thermal interface structure 28 to effectively fill the gaps between the two connecting structures, it should be compressed effectively between the heat removing structure 26 and SoW 24 in certain applications. In many cases, the higher the pressure, the better the thermal contact between the two structures. However, in certain embodiments, the SoW 24 includes circuit elements that can be impacted by external pressure. Therefore, it may be desirable to apply as little pressure as possible for achieving a sufficient bonding strength between the SoW 24 and the heat removing structure 26.

Another adverse effect of applying a high pressure can include strong mechanical coupling between the heat removing structure 26 and SoW 24. Such a mechanical coupling may cause large shear forces between the heat removing structure 26 and SoW 24 under thermal expansion and contraction, which in return can adversely affect the reliability of the assembly.

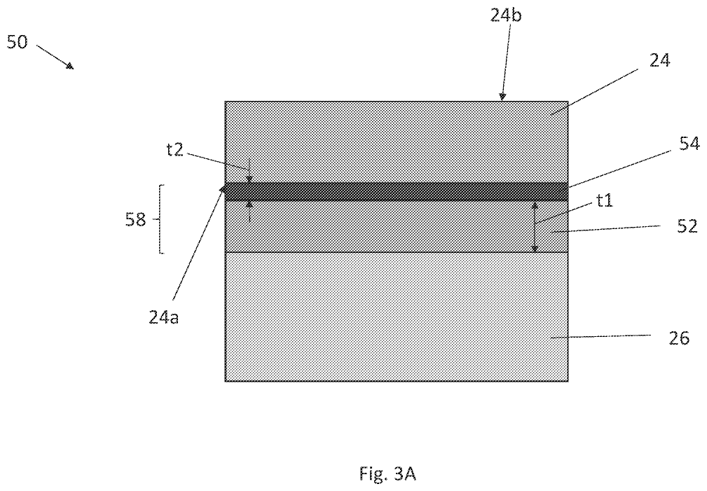

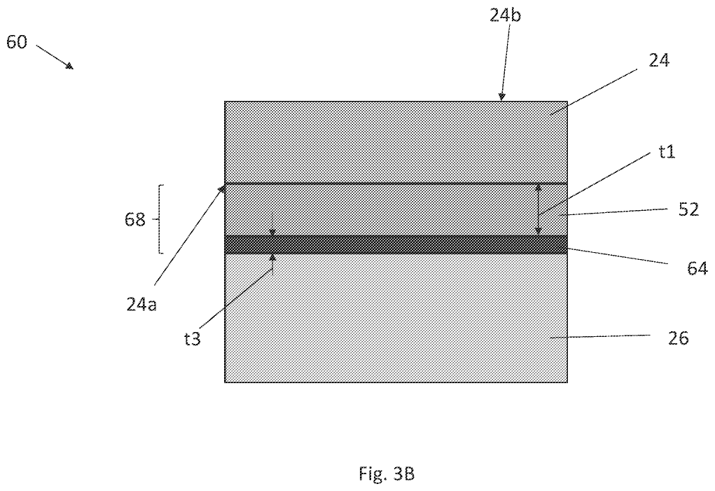

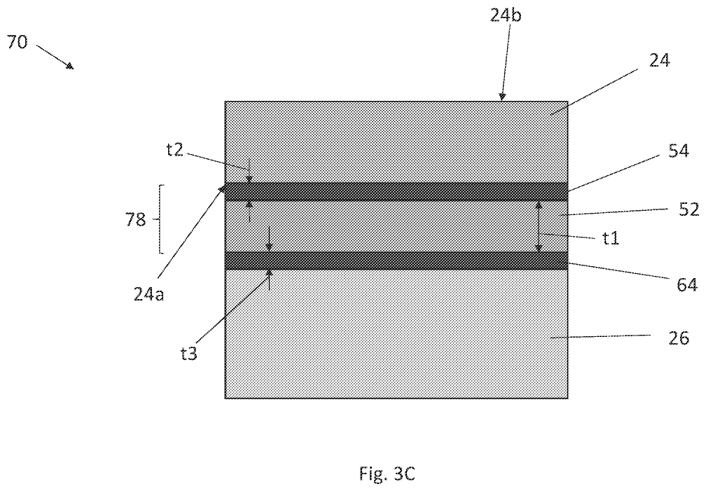

FIGS. 3A-3C illustrate schematic cross sectional side views of SOW assemblies with various thermal interface structures. By combining different types of thermal interface materials or different orientations of the same material, it is possible to maintain a low thermal resistance between the SoW 24 and the heat removing structure 26, while reducing a desired compression pressure and/or reducing a shear coupling between the SoW 24 and the heat removing structure 26. In FIGS. 3A-3C, three different combinations of different thermal interface materials are shown in thermal interface structures.

The embodiments of FIGS. 3A-3C can be advantageous, for example, when a bonding surface has relatively high roughness. The thermal interface structures can achieve one or more of a low contact resistance for high thermal performance, low mechanical clamping force for attaching during manufacturing which can reduce wafer cracking risk and/or increase reliability, or low interfacial shear stress to improve mechanically loose-coupling between the SoW and thermal dissipation structure. Accordingly, the thermal interface structures can achieve good thermal performance, while enabling relatively low pressure bonding and/or low shear stress coupling.

FIG. 3A is a schematic cross sectional side view of a SoW assembly 50 according to an embodiment. Unless otherwise noted, components of the SoW assembly 50 of FIG. 3A can be the same as or generally similar to like components of any SoW assembly disclosed herein. FIG. 3A shows an adhesion layer 54 having a thickness t2 is placed on the heat removing structure side, while thermal interface layer 52 having a thickness t1 is placed on the SoW assembly side. Each one of the thermal interface layer 52 and the adhesion layer 54 can be selected to meet specific specifications of their corresponding side from either the SoW 24 or the heat removing structure 26.

The assembly 50 can include a SoW 24 having a first side 24a and a second side 24b opposite the first side 24a, and a heat removing structure26. The assembly 50 can also include a thermal interface structure 58 that is positioned between the first side 24a of the SoW 24 and the heat removing structure26. The thermal interface structure 58 can comprise a thermal interface layer 52 that is positioned between the first side 24a of SoW 24 and the heat removing structure26, and an adhesion layer 54 that is positioned between the first side 24a of the SoW 24 and the thermal interface layer 52. With the thermal interface layer 52 and the adhesion layer 54, the thermal interface structure 58 can achieve relatively high thermal conductivity and also aid in bonding the SoW 24 and the heat removing structure26 with relatively low pressure.

In some embodiments, the thermal interface layer 52 can comprise a thermally conductive material, such as graphite, carbon, indium, the like, or any alloy thereof. In some embodiments, the thermal interface layer 52 can comprise a dispensable material such as a thermal grease, a putty, or a two-part epoxy. In some embodiments, the thermal interface layer 52 can comprise a pad, such as a cured gap pad, graphite pad, a phase change material pad, or a metallic pad. In some embodiments, the thermal interface layer 52 can comprise vertically aligned graphite that is aligned generally perpendicular to the first side of the SoW 24 or a carbon nanotube.

The adhesion layer 54 can comprise a material that improves an adhesion strength between the SoW 24 and the thermal interface layer 52 as compared bonding the SoW 24 and the thermal interface layer 52 without the adhesion layer 54. In some embodiments, the adhesion layer 54 can beneficially reduce pressure for bonding the SoW 24 and the heat removing structure 26.

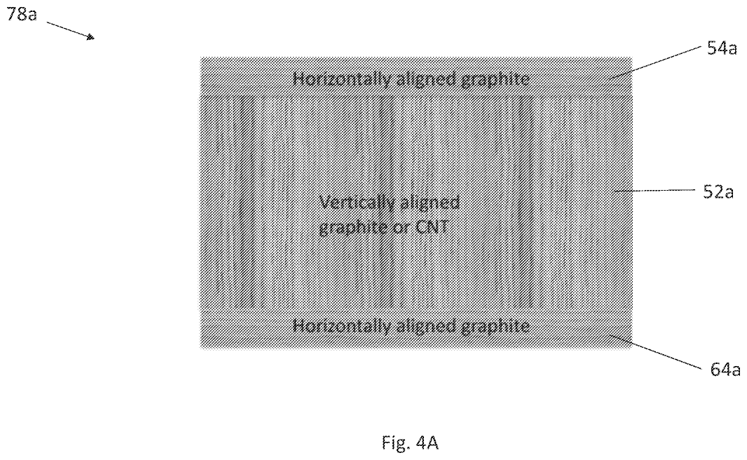

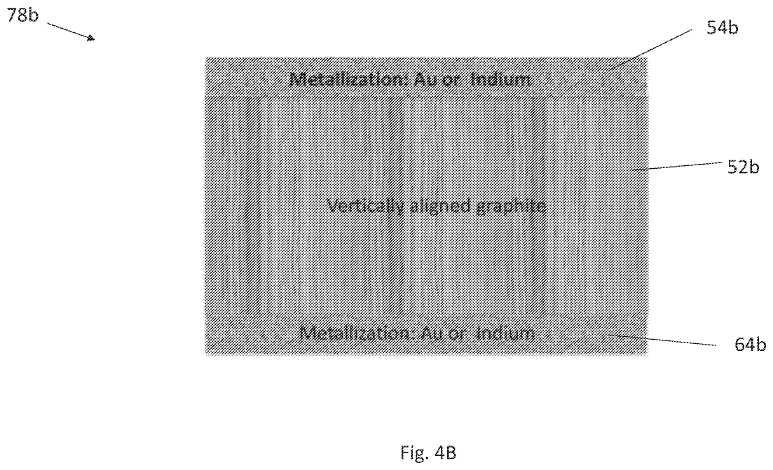

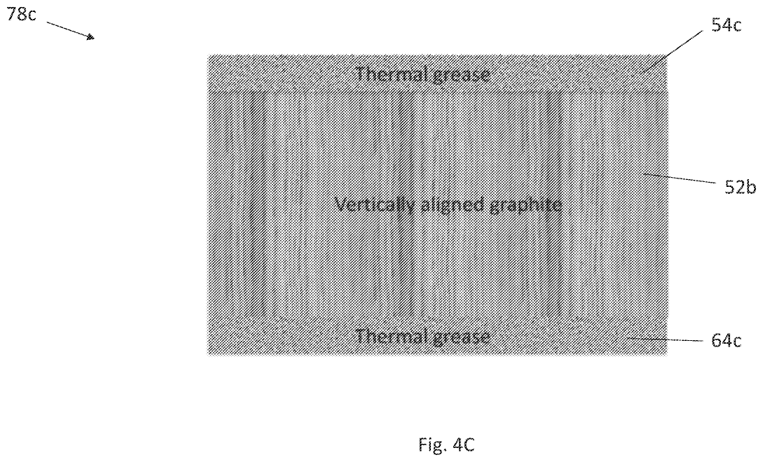

In some embodiments, as examples of how the proposed assembly can be structured, the adhesion layer 54 can comprise a horizontally aligned graphite layer that is aligned generally parallel with the first side 24a of the SoW 24 (e.g., as shown in FIG. 4A), a metallization layer (e.g., as shown in FIG. 4B), or a thermal grease (e.g., as shown in FIG. 4C). For example, the metallization layer can comprise gold and/or indium. The thermal conductivity of the thermal interface layer 52 is typically greater than a thermal conductivity of the adhesion layer 54. In some embodiments, a surface of the adhesion layer 54 can be smoother than a surface of the thermal interface layer 52.

The thermal interface layer 52 has a thickness t1. The thickness t1 of the thermal interface layer 52 can be tuned to meet the thermal, mechanical, and/or manufacturing requirements of each specific application.

The adhesion layer 54 has a thickness t2. The thickness t2 of the adhesion layer 54 can be optimized to provide proper contact between the thermal interface layer 52 and the heat removing structure 26 or the SoW 24, while minimizing the thermal resistance or assembly thickness

FIG. 3B is a schematic cross sectional side view of a SoW assembly 60 according to another embodiment. Unless otherwise noted, components of the SoW assembly 60 of FIG. 3B can be the same as or generally similar to like components of any SoW assembly disclosed herein.

The assembly 60 can include a SoW 24 having a first side 24a and a second side 24b opposite the first side 24a, and a heat removing structure26. The assembly 60 can also include a thermal interface structure 68 that is positioned between the first side 24a of the SoW 24 and the heat removing structure26. The thermal interface structure 68 can comprise a thermal interface layer 52 that is positioned between the first side 24a of SoW 24 and the heat removing structure26, and an adhesion layer 64 that is positioned between the thermal interface layer 52 and the heat removing structure26.

The adhesion layer 64 can comprise a material that improves an adhesion strength between the heat removing structure26 and the thermal interface layer 52 as compared bonding the heat removing structure26 and the thermal interface layer 52 without the adhesion layer 64. In some embodiments, the adhesion layer 64 can beneficially reduce pressure for bonding the SoW 24 and the heat removing structure26.

In some embodiments, the adhesion layer 64 can comprise a horizontally aligned graphite layer that is aligned parallel with the first side 24a of the SoW 24 (e.g., as shown in FIG. 4A), a metallization layer (e.g., as shown in FIG. 4B), or a thermal grease (e.g., as shown in FIG. 4C). For example, the metallization layer can comprise gold or indium. In some embodiments, the thermal conductivity of the thermal interface layer 52 can be greater than a thermal conductivity of the adhesion layer 64. In some embodiments, a surface of the adhesion layer 64 can be smoother than a surface of the thermal interface layer 52.

FIG. 3C is a schematic cross sectional side view of a SoW assembly 70 according to another embodiment. Unless otherwise noted, components of the SoW assembly 70 of FIG. 3C can be the same as or generally similar to like components of any SoW assembly disclosed herein. FIG. 3C shows an embodiment with a TIM structure that includes three layer of thermal interface layers 54, 52, and 64. Thicknesses and materials of layers 54 and 64 can be tuned and optimized for their corresponding mating surfaces.

The assembly 70 can include a SoW 24 having a first side 24a and a second side 24b opposite the first side 24a, and a heat removing structure 26. The assembly 70 can also include a thermal interface structure 78 that is positioned between the first side 24a of the SoW 24 and the heat removing structure 26. The thermal interface structure 78 can comprise a thermal interface layer 52 that is positioned between the first side 24a of SoW 24 and the heat removing structure 26, an adhesion layer 54 that is positioned between the first side 24a of SoW 24 and the thermal interface layer 52, and another adhesion layer 64 that is positioned between the thermal interface layer 52 and the heat removing structure 26. In some embodiments, the adhesion layer 54 and the adhesion layer 64 can comprise the same material. In other embodiments, the adhesion layer 54 and the adhesion layer 64 can comprise different materials.

FIGS. 4A-4C illustrate various embodiments of a thermal interface structure. Although the thermal interface structures include two adhesion layers, any suitable principles and advantages of these structures can be implemented in applications where a thermal interface structure includes a single adhesion layer. Moreover, any suitable combination of features of the embodiments of FIGS. 4A-4C can be implemented together with each other.

FIG. 4A is a schematic cross sectional side view of a thermal interface structure 78a according to an embodiment. The thermal interface structure 78a includes a thermal interface layer 52a that comprises vertically aligned graphite or carbon nanotubes, an adhesion layer 54a that comprises a horizontally aligned graphite, and an adhesion layer 64a that comprises a horizontally aligned graphite. Vertically aligned graphite and carbon nanotubes are examples of thermal interface layers with good thermal performance. The vertically aligned graphite can be aligned generally perpendicular to bonding surfaces of the thermal interface layer 52a and the adhesion layers 54a, 64a. Horizontally aligned graphite is an example of an adhesion layer with desirable compression and adhesion properties for bonding. Other suitable adhesion layers include polymer layers. In the embodiment illustrated in FIG. 4A, horizontally aligned graphite can be aligned generally parallel with the bonding surfaces the thermal interface layer 52a and the adhesion layer 54a, 64a. The vertically aligned graphite and the horizontally aligned graphite are aligned generally perpendicular to each other in the thermal interface structure 78a.

The horizontally aligned graphite of the adhesion layer 54a, 64a can have a more flat or smooth bonding surface relative to the bonding surfaces of the thermal interface layer 52a. Such flatness or smoothness of the bonding surface of the horizontally aligned graphite can enable the adhesion layer 54a, 64a to bond with other elements, such as the SoW 24 and the heat removing structure 26 shown in FIGS. 2-3C, with a relatively low pressure.

FIG. 4B is a schematic cross sectional side view of a thermal interface structure 78b according to another embodiment. The thermal interface structure 78b includes a thermal interface layer 52b that comprises vertically aligned graphite, an adhesion layer 54b that comprises a metallization layer, and an adhesion layer 64b that comprises a metallization layer. The vertically aligned graphite can be aligned generally perpendicular to bonding surfaces of the thermal interface layer 52b and the adhesion layer 54b, 64b. In some embodiments, the metallization layer of the adhesion layer 54b, 64b can comprise a soft metal, such as gold or indium.

The metallization layer of the adhesion layer 54b, 64b can have a more flat or smooth bonding surface relative to bonding surfaces of the thermal interface layer 52b. Such flatness and/or smoothness of the bonding surface of the metallization layer can enable the adhesion layer 54b, 64b to bond with other elements, such as the SoW 24 and the heat removing structure26 shown in FIGS. 2-3C, with a relatively low pressure.

FIG. 4C is a schematic cross sectional side view of a thermal interface structure 78c according to another embodiment. The thermal interface structure 78c includes a thermal interface layer 52b that comprises vertically aligned graphite, an adhesion layer 54c that comprises a thermal grease, and an adhesion layer 64c that comprises a thermal grease. The vertically aligned graphite can be aligned generally perpendicular to bonding surfaces of the thermal interface layer 52b and the adhesion layer 54b, 64b

The thermal grease of the adhesion layer 54b, 64b can be in a liquid form when applied on the thermal interface layer 52b before bonding to elements, such as the SoW 24 and the heat removing structure26 shown in FIGS. 2-3C. The thermal grease enables low pressure bonding between the thermal interface layer 52b and the elements.

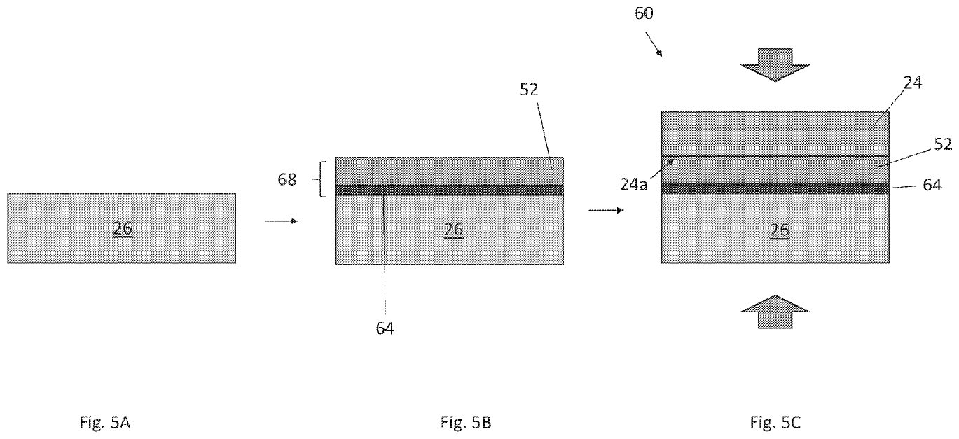

FIGS. 5A-5C illustrate structures at different steps in manufacturing the assembly 60 of FIG. 3B according to an embodiment. At FIG. 5A, a heat removing structure 26 can be provided. The heat removing structure 26 can have a generally flat bonding surface.

At FIG. 5B, a thermal interface structure 68 that comprises a thermal interface layer 52 and an adhesion layer 64 can be provided on the bonding surface of the heat removing structure 26. In some embodiments, the thermal interface structure 68 can be pre-formed before being positioned on the heat removing structure26. In other words, the thermal interface layer 52 and the adhesion layer 64 can be separately formed and provided on the bonding surface of the heat removing structure26. For example, the adhesion layer 64 can be formed on a surface of the thermal interface layer 52 and the pre-formed thermal interface structure 68 can be provided. In some other embodiments, the adhesion layer 64 can be formed on the bonding surface of the heat removing structure26, then the thermal interface layer 52 can be formed over the adhesion layer 64.

At FIG. 5C, a SoW 24 that has a first side 24a can be provided. The first side 24a of the SoW 24 faces the thermal interface layer 52. After the SoW 24 is provided, a pressure can be applied in a vertical direction shown by arrows in FIG. 5C to bond the resulting stack of elements together.

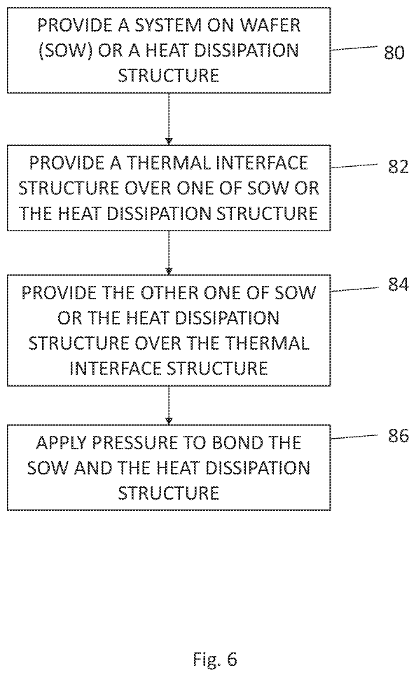

FIG. 6 is a flow chart showing a process of manufacturing a SoW assembly according to an embodiment. The process can be used to manufacture any of the SoW assemblies disclosed herein. The process of manufacturing the assembly can include steps 80, 82, 84, and 86. At the step 80, a SoW or a heat removing structure can be provided.

At the step 82, a thermal interface structure can be provided over one of the SoW or the heat removing structure provided at the step 80. The thermal interface structure can comprise a thermal interface layer and an adhesion layer in accordance with any suitable principles and advantages disclosed herein. In some embodiments, the thermal interface structure can also comprise another adhesion layer such that the thermal interface layer is positioned between the two adhesion layers. In some embodiments, the thermal interface structure can be pre-formed before provided over the one of the SoW or the heat dissipation structure. In some other embodiments, the thermal interface layer and the adhesion layer can be provided separately to form the thermal interface structure over the one of the SoW or the heat dissipation structure.

At the step 84, the other one of the SoW or the heat removing structure can be provided over the thermal interface structure such that the thermal interface structure is positioned between the SoW and the heat removing structure to form a vertical stack of the SoW, the thermal interface structure, and the heat dissipation structure.

At the step 86, a pressure can be applied in a vertical direction to bond the resulting stack of the SoW, the thermal interface structure, and the heat dissipation structure.

As discussed above, a thermal dissipation structure can be attached to a SoW. A layer of thermal interface layer between the thermal dissipation structure and the SoW can reduce the contact resistance and facilitate the heat transport from SoW to the thermal dissipation structure. In this configuration, the thermal interface layer can cover an extended surface area of 12″ diameter for a typical wafer size. With a thermal interface layer (e.g., a thermal grease layer) having a typical thickness of a few thousandths of an inch, the thermal interface layer can have an extreme aspect ratio. This can present technical challenges in manufacturing and process control, and also can pose risks to the reliability of the thermal interface layer. Reliability issues include, but are not limited to, pump out, void, uneven thickness, and the like. One common type of thermal interface material in high performance systems is thermal grease. A thermal grease, however, can be prone to pump out, which is known failure mode for this type of thermal interface material. For an application of grease on a SoW, with extreme aspect ratios as described above, the pump out risk can be intensified.

To mitigate such risks, technical solutions are provided for thermal interface layers to improve the thermal interface layer application process, create a more even TIM thickness across the wafer, and reduce the risk of TIM pump out by having excess material available.

Grooves can be included between a SoW and a thermal dissipation structure. The thermal interface layer, such as a thermal grease layer, can be included in the grooves and as a thin layer. The extra volume in these grooves can act as a reservoir to collect excess thermal interface material layer to facilitate a more uniform layer during assembly when thermal interface material is dispensed. The preserved thermal interface material in the groves can then compensate for the increased gap between the thermal dissipation structure and the SoW in case of thermal expansion of different components of the system and/or change in mechanical force that keeps them together.

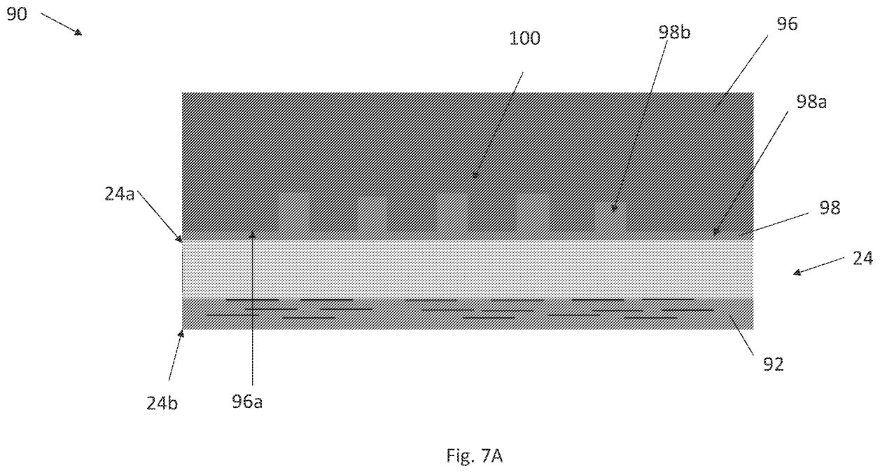

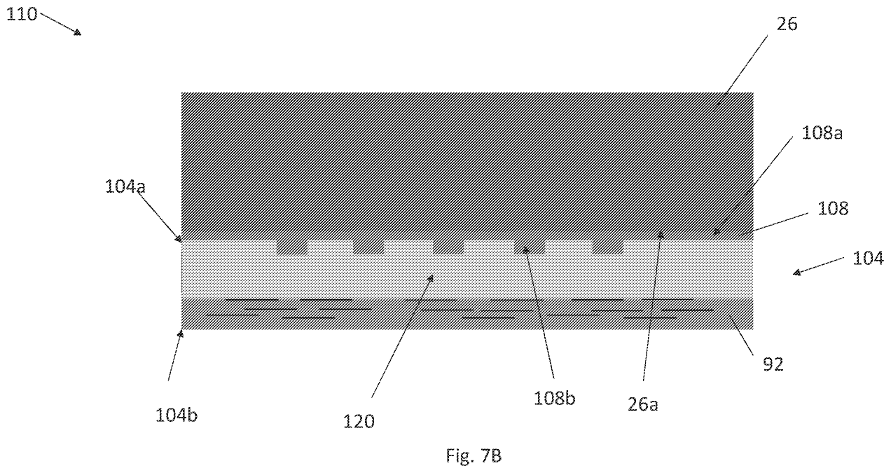

FIGS. 7A and 7B show SoW assemblies with grooves and thermal interface material in the grooves. In FIG. 7A, grooves are present in the heat removing structure. In FIG. 7B, grooves are present in the SoW. Grooves can be present in both the SoW and the thermal dissipation structure in certain applications.

FIG. 7A is a schematic cross sectional side view of a SoW assembly 90 according to an embodiment. Unless otherwise noted, components of the SoW assembly 90 of FIG. 7A can be the same as or generally similar to like components of any SoW assembly disclosed herein.

The assembly 90 can include a SoW 24 that has a first side 24a and a second side 24b opposite the first side 24a, and a heat removing structure %. The SoW 24 can comprise a redistribution layer (RDL) 92 formed on the second side 24b. The assembly 90 can also include a thermal interface structure 98 that is positioned between the first side 24a of the SoW 24 and the heat removing structure 96. The heat removing structure 96 can comprise a plurality of grooves 100 formed on or at a bonding surface 96a. The thermal interface structure 98 can comprise a first portion 98a that extends along a bonding interface between the first side 24a of the SoW 24 and the bonding surface % a of the heat removing structure %, and a second portion 98b that is disposed in the plurality of grooves 100.

The thermal interface structure 98 can comprise a thermal grease. The thermal grease can dry out or pump out overtime and result in formation of a gap or void at the bonding interface between the first side 24a of the SoW 24 and the bonding surface 96a of the heat removing structure 96. The grooves 100 of the heat removing structure 96 can serve as a reservoir for the second portion 98b of the thermal interface structure 98. The second portion 98b of the thermal interface structure 98 in the grooves 100 can prevent or mitigate formation of a gap or void near the bonding interface between the first side 24a of the SoW 24 and the bonding surface % a of the heat removing structure 96. Therefore, a sufficient contact between the first side 24a of the SoW 24 and the bonding surface 96a of the heat removing structure 96 can be maintained.

In some embodiments, the thermal interface structure 98 can comprise a multi-layer structure having a thermal interface layer and an adhesion layer (e.g., as in accordance with any of FIGS. 3A-3C and 4C).

FIG. 7B is a schematic cross sectional side view of a SoW assembly 110 according to an embodiment. Unless otherwise noted, components of the SoW assembly 110 of FIG. 7B can be the same as or generally similar to like components of any SoW assembly disclosed herein.

The SoW assembly 110 can include a SoW 104 that has a first side 104a and a second side 104b opposite the first side 104a, and a heat removing structure 26. The SoW 104 can comprise a redistribution layer (RDL) 92 formed on the second side 104b. The SoW assembly 110 can also include a thermal interface structure 108 that is positioned between the first side 104a of the SoW 104 and the heat removing structure 26. The SoW 104 can comprise a plurality of grooves 120 formed on or at the first side 104a. The thermal interface structure 108 can comprise a first portion 108a that extends along a bonding interface between the first side 24a of the SoW 24 and a boding surface 26a of the heat removing structure 26, and a second portion 108b that is disposed in the plurality of grooves 120.

The thermal interface structure 108 can comprise a thermal grease. The thermal grease can dry out and loose its volume overtime and result in formation of a gap or void at the bonding interface between the first side 104a of the SoW 104 and the bonding surface 96a of the heat removing structure 96. The grooves 120 of the SoW 104 can serve as a reservoir for the second portion 108b of the thermal interface structure 108. Such groves can be etched out or carved out of the molding layer between the dies. The second portion 108b of the thermal interface structure 108 in the grooves 120 can prevent or mitigate formation of a gap or void near the bonding interface between the first side 104a of the SoW 104 and the boding surface 26a of the heat removing structure 26. Therefore, a sufficient contact between the first side 104a of the SoW 104 and the boding surface 26a of the heat removing structure 26 can be maintained.

In some embodiments, the thermal interface structure 98 can comprise a multi-layer structure having a thermal interface layer and an adhesion layer (e.g., in accordance with any of FIGS. 3A-3C and 4C). In some embodiments, the SoW 104 illustrated in FIG. 7B and the heat removing structure 96 illustrated in FIG. 7A can be implemented in a SoW assembly. In such embodiments, portions of a thermal interface structure can be disposed in both the grooves 120 formed with the SoW 104 and the grooves 100 formed with the heat removing structure 96.

Although embodiments disclosed herein may related to a thermal interface structure between a SoW and a heat dissipation structure, any suitable principles and advantages disclosed herein can be applied to a thermal interface structure anywhere in a processing system, such as between a heat removing structure and a substrate or a wafer. For instance, thermal interface structures disclosed herein can be positioned between a system on a chip (SoC) and a thermal dissipation structure. In certain applications, thermal interface structures disclosed herein can be positioned between an electronic component with one or more sensitive circuit elements and a thermal dissipation structure. As another example, thermal interface structures disclosed herein can be positioned between an active cooling system and a substrate or a wafer.

Unless the context clearly requires otherwise, throughout the description and the claims, the words “comprise,” “comprising,” “include,” “including” and the like are to be construed in an inclusive sense, as opposed to an exclusive or exhaustive sense, that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

The foregoing description has been described with reference to specific embodiments. However, the illustrative discussions above are not intended to be exhaustive or to limit the inventions to the precise forms described. Many modifications and variations are possible in view of the above teachings. Others skilled in the art are thereby enabled to best utilize the techniques and various embodiments with various modifications as suited to various uses.

Although the disclosure and examples have been described with reference to the accompanying drawings, various changes and modifications will become apparent to those skilled in the art. Such changes and modifications are to be understood as being included within the scope of the disclosure.

1. An electronic assembly comprising:
an electronic component having a first side;
a heat removing structure coupled to the first side of the electronic component; and
a thermal interface structure comprising a thermal interface layer and an adhesion layer, the thermal interface layer positioned between the first side of the electronic component and the heat removing structure, and the adhesion layer positioned between the heat removing structure and the thermal interface layer.

2. The assembly of claim 1, wherein the electronic component is a system on a wafer (SoW).

3. The assembly of claim 1, wherein the thermal interface layer comprises a vertically aligned graphite layer that is aligned generally perpendicular to the first side of the electronic component.

4. The assembly of claim 1, wherein the thermal interface layer comprises a carbon nanotube layer.

5. The assembly of claim 1, wherein a thickness of the thermal interface layer is greater than a thickness of the adhesion layer.

6. The assembly of claim 1, wherein the adhesion layer comprises a horizontally aligned graphite layer that is aligned generally parallel to the first side of the electronic component.

7. The assembly of claim 1, wherein the thermal interface layer comprises a vertically aligned graphite layer that is aligned generally perpendicular to the first side of the electronic component, and the adhesion layer comprises a horizontally aligned graphite layer that is aligned generally parallel to the first side of the electronic component.

8. The assembly of claim 1, wherein the adhesion layer comprises a metal adhesion layer or a thermal grease layer.

9. (canceled)

10. (canceled)

11. The assembly of claim 1, further comprising a second adhesion layer between the electronic component and the thermal interface layer.

12. The assembly of claim 1, further comprising a control board coupled to a second side of the electronic component opposite the first side, and a second heat removing structure between the second side of the electronic component and the control board.

13. A method of manufacturing an electronic assembly, the method comprising:
providing (a) a thermal interface layer between a first side of an electronic component and a heat removing structure and (b) an adhesion layer between the thermal interface layer and the heat removing structure; and
applying pressure to bond the electronic component and the heat removing structure by way of the thermal interface layer.

14. The method of claim 13, wherein the electronic assembly is a system on a wafer assembly and the electronic component is a system on a wafer (SoW).

15. The method of claim 13, wherein a thickness of the thermal interface layer is greater than a thickness of the adhesion layer.

16. The method of claim 13, wherein the adhesion layer comprises one of:
a horizontally aligned graphite layer that is aligned generally parallel with a first side of the electronic component;
a metal adhesion layer; or
a thermal grease layer.

17. The method of claim 13, further comprising a second adhesion layer between the electronic component and the thermal interface layer, wherein the adhesion layer and the second adhesion layer comprise a same material.

18. The method of claim 13, further comprising providing a control board to a second side of the electronic component opposite the first side, and providing a second heat removing structure between the second side of the electronic component and the control board.

19. A wafer assembly comprising:
a wafer having a first side;
a heat removing structure coupled to the wafer;
a thermal interface structure disposed between and bonding the first side of the wafer and the heat removing structure, the thermal interface structure comprising a thermal interface material; and
a groove between the wafer and the heat removing structure, at least a portion of the thermal interface material is disposed in the groove.

20. The assembly of claim 19, wherein the groove is in a surface of the wafer.

21. The assembly of claim 19, wherein the groove is in a surface of the heat removing structure.

22. (canceled)

23. (canceled)

24. The assembly of claim 19, further comprising a control board coupled to a second side of the wafer opposite the first side, and a second heat removing structure between the second side of the wafer and the control board.
